(19) United States
(12) Patent Application Publication
(10) Pub. No.: US 2013/0126922 A1
(43) Pub. Date: May 23, 2013

(54) LIGHT EMITTING DIODE INCORPORATING LIGHT CONVERTING MATERIAL

(71) Applicant: CHIH-MING LAI, Chu-Nan (TW)

(72) Inventor: CHIH-MING LAI, Chu-Nan (TW)

(73) Assignee: FOXSEMICON INTEGRATED TECHNOLOGY, INC., Chu-Nan (TW)

(21) Appl. No.: 13/300,664

(22) Filed: Nov. 21, 2011

(51) Int. Cl. H01L 33/58; H01L 33/50

(52) U.S. Cl. 257/98; 257/E33.061; 257/E33.073

(57) ABSTRACT

An LED includes an LED chip, an encapsulant for encapsulating the LED chip, and a lens attached to the encapsulant. The lens includes a main body, and a light converting unit with a light converting material distributed therein. The main body defines a receiving space facing the LED chip. The light converting unit is received in the main body. Light emitted by the LED chip passes through the light converting unit and then enters into the main body of the lens. The light converting material of the light converting unit changes a wavelength of the light of the LED chip when the light passes through the light converting unit.

### BACKGROUND

1. Technical Field

The present disclosure relates to light-emitting diodes (LEDs), and more particularly to an LED incorporating light converting material.

2. Description of Related Art

As a new light source, light emitting diodes (LEDs) have several advantages over incandescent and fluorescent lamps, including energy-efficient, long life and environmentally friendly. White LEDs are widely used for illumination due to their high brightness. Typically, a white LED includes a blue LED chip with a yellow fluorescent powder coated at an outer surface thereof. In operation, a portion of blue light emitted by the blue LED chip activates the yellow fluorescent powder to emit yellow light, and the yellow light mixes with the other portion of the blue light to thereby obtain white light.

However, as the fluorescent powder is directly deposited on the LED chip, heat generated by the LED chip may result in non-uniform absorption of blue light and emission of yellow light of the fluorescent powder. The white light emitted by the LED is thus not uniform in color temperature. Furthermore, since the LED chip is very small in size, the outer surface of the LED chip is inconvenient to be deposited with the fluorescent powder thereon, which results in that a manufacturing process of the white LED is time-consuming and a manufacturing cost of the white LED is accordingly high.

What is needed, therefore, is an LED which can overcome the limitations described.

### BRIEF DESCRIPTION OF THE DRAWINGS

FIG. 1 is an assembled, schematic view of an LED in accordance with an embodiment of the disclosure.

FIG. 2 is an exploded view of the LED of FIG. 1.

FIG. 3 is a diagram illustrating a luminous intensity distribution of an LED chip of the LED of FIG. 1.

### DETAILED DESCRIPTION

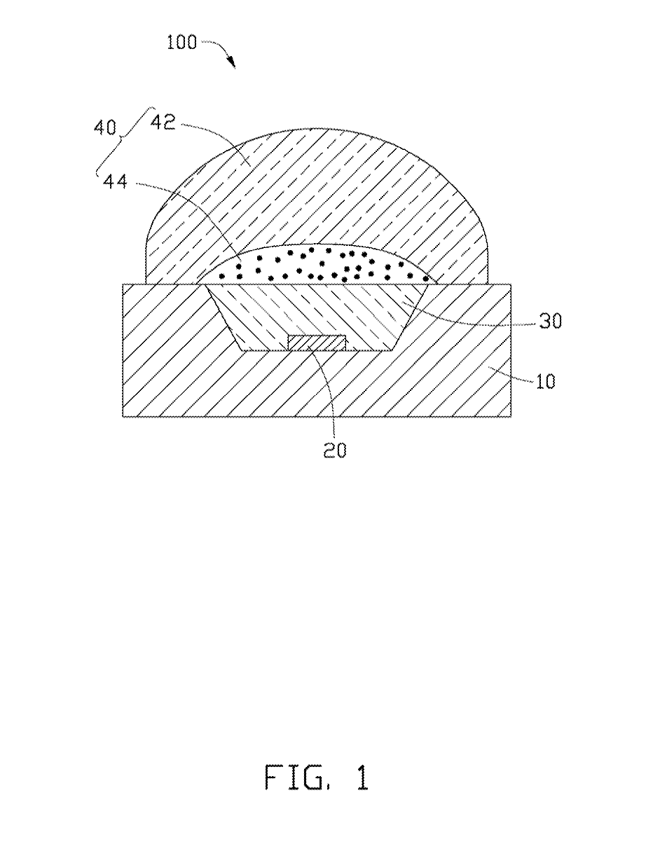

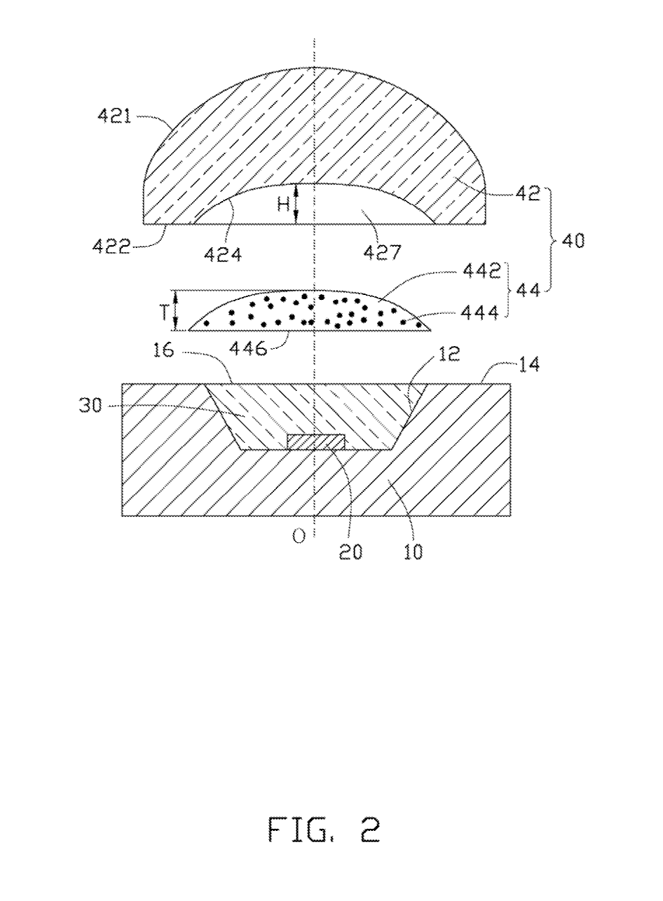

Referring to FIGS. 1-2, an LED 100 in accordance with an embodiment is shown. The LED 100 includes a substrate 10, an LED chip 20 supported by the substrate 10, an encapsulation 30 encapsulating the LED chip 20, and a lens 40 attached to the encapsulation 30. In this embodiment, the LED chip 20 is a blue LED chip 20, and the LED chip 20 emits blue light during operation.

The substrate 10 can be made of a metallic material, a ceramic material with properties of electrical insulation and high thermal conductivity, or a semiconductor material. Particularly, the metallic material can be copper, aluminum or alloy thereof. The ceramic material can be Al₂O₃, AlN, SiC or BeO₂. The semiconductor material can be silicon. A groove 12 with a trapeziform cross section is defined at a top side of the substrate 10 for receiving the LED chip 20. The groove 12 extends through a top surface 14 of the substrate 10, and accordingly, an opening 16 is defined at the top surface 14 of the substrate 10 for allowing the LED chip 20 to enter the groove 12. A size of the groove 12 gradually increases along a bottom-to-top direction of the substrate 10. The LED chip 20 is received in the groove 12 and attached to an inner surface of the groove 12. The encapsulation 30 is filled in the groove 12 to encapsulate the LED chip 20. A top face of the encapsulation 30 is coplanar with the top surface 14 of the substrate 10.

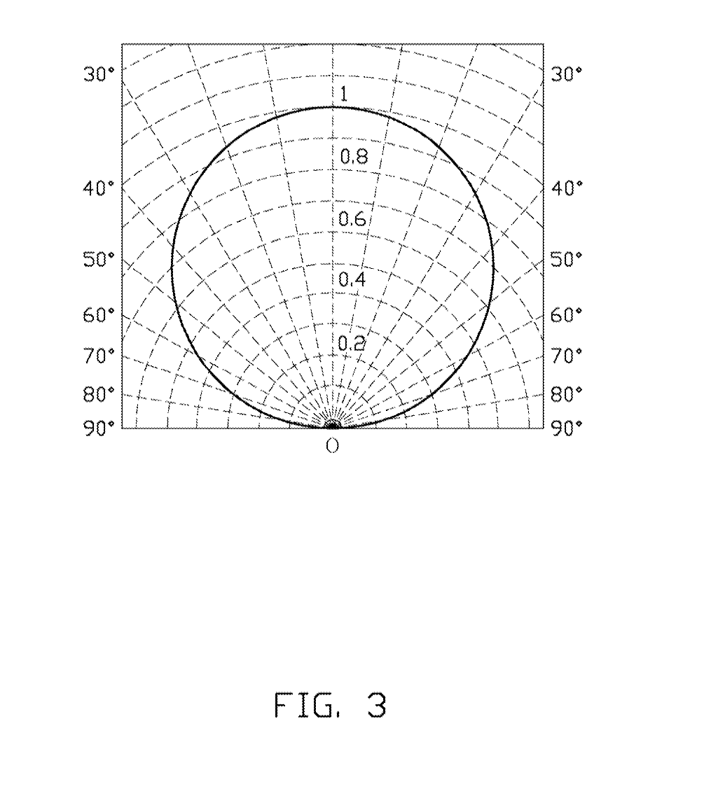

Referring to FIG. 3, a diagram illustrating a relationship between a luminous intensity I of light of the LED chip 20 and a radiation angle θ of the light is shown. The luminous intensity I of the light generated by the LED chip 20 and the radiation angle θ are in Lambertian distribution and according to the formula: I=I₀×cos θ, wherein 0°≦θ≦90°, and I₀ is a luminous intensity at a central axis O of the LED chip 20, and the radiation angle θ is an angle between the light and the central axis O.

The lens 40 includes a main body 42 and a light converting unit 44 attached to a bottom of the main body 42. The main body 42 has a substantially hemispherical shape, including a hemispherical outer face 421 and a flat bottom face 422. A central portion 424 of the bottom face 422 is recessed upwardly and inwardly, and thus a receiving space 427 is defined therein for receiving the light converting unit 44. The receiving space 427 faces the LED chip 20. The receiving space 427 has a depth H gradually decreasing from a central portion towards an outer peripheral portion thereof. The central portion of the receiving space 427 is aligned with the LED chip 20. Particularly, the depth H of the receiving space 427 and the radiation angle θ are according to the following formula: H=H₀×cos θ, wherein 0°≦0≦90°, H₀ is a depth of the receiving space 427 at the central axis O of the LED chip 20, and the radiation angle θ is the angle between the light and the central axis O. That is, the depth H of the receiving space 427 and the radiation angle θ are also in Lambertian distribution. In addition, a maximum depth Hₘₐₓ of the receiving space 427 is preferably not exceeding 500 μm, and more preferably not exceeding 300 μm.

The light converting unit 44 includes a base material 442 and a light converting material 444 such as fluorescent powder. The light converting material 444 is uniformly doped and distributed in the base material 442. The base material 442 is made of light transparent material, such as resin, epoxy resin, silicone, polyethylene terephthalate, polycarbonate (PC), acrylics, polymethyl methacrylate (PMMA), low temperature melting glass, SiNₓ or SiO₂.

The light converting material 444 is fluorescent powder. The fluorescent powder can be of sulfides, aluminates, oxides, silicates, nitrides or oxinitride. Particularly, the fluorescent powder can be of Ca₂Al₁₂O₁₉:Mn, (Ca,Sr,Ba)Al₁₂O₄:Eu, Y₃Al₅O₁₂:Ce³⁺(YAG), Tb₃Al₅O₁₂:Ce³⁺(TAG), BaMgAl₁₀O₁₇:Eu²⁺(Mn²⁺), Ca₂Si₅N₈:Eu²⁺, (Ca,Sr,Ba)S:Eu²⁺, (Mg,Ca,Sr,Ba)₂SiO₄:Eu²⁺, (Mg,Ca,Sr,Ba)₃Si₂O₇:Eu²⁺, Ca₈Mg(SiO₄)₄Cl₂:Eu²⁺, Y₂O₂S:Eu³⁺, (Sr,Ca,Ba)SiₓO_{y}N_{z}:Eu²⁺, (Ca,Mg,Y)Si_{w}AlₓO_{y}N_{z}:Eu²⁺, CdS, CdTe or CdSe. In this embodiment, the light converting material 444 is yellow fluorescent powder. Thus, the LED 100 is a white LED.

The light converting unit 44 can be formed in the receiving space 427 by a method such as spray coating or screen printing. The light converting unit 44 has a shape matching with the receiving space 427 of the main body 42. A bottom surface 446 of the light converting unit 44 is coplanar with the bottom face 422 of the main body 42 beside the receiving space 427. A size of the bottom surface 446 of the light converting unit 44 is slightly larger than that of the opening 16 of the top surface 14 of the substrate 10.

Since the shape of the light converting unit 44 matches the receiving space 427 of the main body 42, the light converting unit 44 is thus fittingly received in the receiving space 427 and aligned with the LED chip 20. Accordingly, the light converting unit 44 has a thickness T decreasing gradually from a central portion towards an outer peripheral portion thereof. The thickness T of the light converting unit 44 and the radiation angle θ are according to the following formula: T=T₀×cos θ, wherein 0°≦0≦90°, T₀ is a thickness of the light converting unit 44 at the central axis O of the LED chip 20, and the radiation angle θ is the angle between the light and the central axis O. Namely, the thickness T of the light converting unit 44 and the radiation angle θ are also in Lambertian distribution. In addition, a maximum thickness Tₘₐₓ of the light converting unit 44 is preferably not exceeding 500 μm, and more preferably not exceeding 300 μm, corresponding to the depth of the receiving space 427 of the main body 42.

In assembly, the lens 40 is attached to the top surface 14 of the substrate 10, with the light converting unit 44 fully covering the opening 16 of the substrate 10, and the bottom surface 446 of the light converting unit 44 abutting against the top face of the encapsulation 30. Thus, all of the light emitted by the LED chip 20 passes through the light converting unit 44 and then enters into the main body 42 of the lens 40. The light converting material 444 of the light converting unit 44 changes a wavelength of a portion of the light of the LED chip 20 when the portion of the light passes through the light converting unit 44. As the light converting material 444 is uniformly distributed in the light converting unit 44 of the lens 40 and disposed far away from the LED chip 20, thus the light converting material 444 is avoided to be heated by the LED chip 20 during operation of the LED chip 20. In addition, since the light converting unit 44 is formed with the lens 40, a manufacturing process of the LED 100 is relatively simple and convenient.

It is to be understood, however, that even though numerous characteristics and advantages of certain embodiment(s) have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

1. An LED comprising:
an LED chip;
an encapsulation encapsulating the LED chip;
a lens attached to the encapsulation, the lens comprising a main body and a light converting unit, a light converting material distributed in the light converting unit, the main body defining a receiving space facing the LED chip, the light converting unit received in the receiving space, light emitted by the LED chip passing through the light converting unit and then entering into the main body of the lens, the light converting material changing a wavelength of the light of the LED chip when the light passes through the light converting unit; and
a substrate, the substrate defining a groove therein for receiving the LED chip, the groove extending through a top surface of the substrate, wherein the encapsulation is disposed in the groove, the encapsulation has a top face coplanar with the top surface of the substrate, and a bottom of the light converting unit abuts against the top face of the encapsulation.

2. The LED of claim 1, wherein a luminous intensity I of light generated by the LED chip and a radiation angle θ of the light are in Lambertian distribution and according to the formula: I=I₀×cos θ0, wherein 0°≦0≦90°, and I₀ is a luminous intensity at a central axis of the LED chip, and the radiation angle θ is an angle between the light and the central axis, the receiving space of the main body of the lens is aligned with the LED chip, and a depth of the receiving space is also in Lambertian distribution relative to the radiation angle θ.

3. The LED of claim 2, wherein the light converting unit has a shape matching with the receiving space of the main body, and a thickness of the light converting unit is also in Lambertian distribution relative to the radiation angle θ.

4. The LED of claim 1, wherein the light converting unit has a maximum thickness not exceeding 500 μm.

5. The LED of claim 1, wherein the light converting unit has a maximum thickness not exceeding 300 μm.

6-7. (canceled)

8. The LED of claim 1, wherein an opening is defined at the top surface of the substrate corresponding to the groove, a bottom surface of the light converting unit of the lens fully covers the opening of the groove at the top surface of the substrate.

9. The LED of claim 1, wherein the light converting unit is formed in the main body by a method of spray coating or screen printing.

10. The LED of claim 1, wherein the light converting unit further comprises a base material, and the light converting material is fluorescent powder distributed in the base material.

11. The LED of claim 1, wherein the receiving space has a depth decreasing gradually from a central portion towards an outer peripheral portion thereof, the light converting unit has a shape matching with the receiving space of the main body and is fittingly received in the receiving space of the main body.

12. The LED of claim 1, wherein the main body has a substantially hemispherical shape, including a hemispherical outer face and a flat bottom face, and a central portion of the bottom face is recessed upwardly and inwardly to form the receiving space in the main body.
